(19) United States
(12) Patent Application Publication
(10) Pub. No.: US 2024/0039462 A1
(43) Pub. Date: Feb. 1, 2024

(54) DAMPER SYSTEM AND JUNCTION BOX FOR LAMINATED SOLAR PANEL AND METHOD OF MANUFACTURE

(71) Applicant: APTERA MOTORS CORP., San Diego, CA (US)

(72) Inventor: Anuj M. THAKKAR, San Diego, FL (US)

(73) Assignee: APTERA MOTORS CORP., San Diego, CA (US)

(21) Appl. No.: 18/361,904

(22) Filed: Jul. 30, 2023

Related U.S. Application Data
(60) Provisional application No. 63/393,937, filed on Jul. 31, 2022.

(51) Int. Cl. H02S 30/10; H02S 20/00; H02S 40/34; F16F 7/12

(52) U.S. Cl. CPC H02S 30/10; H02S 20/00; H02S 40/34; F16F 7/12

(57) ABSTRACT

A solar module for industrial applications is disclosed that includes a solar panel coupled to a damper. The damper provides support against static and dynamic loads with reduced risk of damage to the solar cells in applications such as architectural, marine, aeronautical, terrestrial and/or other structural panels, and to reduce noise, vibration and harshness for industrial utility. The solar panel electrical terminations may be housed in one or more junction boxes formed from flexible material of the damper, and having simplified electrical connections with strain relief. The solar module with integrated solar panel, damper and junction boxes constitutes a lightweight, durable body panel with a reduced number of components that may be manufactured in high volume and at low cost.

### CROSS REFERENCE TO RELATED APPLICATIONS

This application claims priority to U.S. Provisional Patent Application No. 63/393,937, filed Jul. 31, 2022, entitled, “DAMPER SYSTEM AND JUNCTION BOX FOR LAMINATE SOLAR PANEL AND METHOD OF MANUFACTURE”, the disclosure of which is incorporated by reference herein in its entirety.

### FIELD OF THE INVENTION

The present disclosure relates generally to curved, laminated, solar-enabled panels secured to a structure. In particular, the present disclosure relates to an apparatus, system and method for mechanically and electrically coupling curved, laminated, solar-enabled vehicular body panels to a vehicle body and/or other support structure.

### BACKGROUND OF THE INVENTION

Industrial and consumer trends, driven by climate change and desire for higher efficiency curved solar panels incorporated into structures in applications such as architectural, marine, aeronautical, terrestrial and/or other structural panels. For example, solar panels employed in transportation applications use panels conforming to the underlying geometry of the vehicle, invoking complex curvatures, such as single or doubly curved solar panels. Solar panels of this sort are subjected to environmental and use conditions including vibrations beyond that experienced by a stationary panel, i.e., flat panel, which results in a variety of potential failure modes. Furthermore, the actual manufacturing of such a curved solar panel including how the panel interfaces and/or couples to surrounding components greatly impacts its performance and longevity of the vehicle, and the performance and longevity of associated components.

Additionally, a solar panel design to conform to a structure should withstand loading conditions, both static and dynamic. Static loading conditions also should withstand loads from expected human contact such as, for example, a person exerting force on the hood, roof, or trunk. It is therefore desirable to develop an apparatus and system that provides for a reduction in solar panel flexion capable of imparting a load that induces failure-level stress in the solar cells under static loading conditions. Consequently, there is a need for a solar panel design should that withstands dynamic loading conditions may include shocks, vibrations, cycle fatigue, and other forces that affect performance, longevity, and passenger comfort.

In addition, a solar panel design may vibrate harmonically to contribute to vehicle noise, vibration, and harshness (NVH) such as, for example, through the transmission of vibrations from wind or noise to the cabin, which may result in varying degrees of passenger dissatisfaction. Rattling or undampened external noises are some examples of NVH attributable to such forces experienced by a solar panel; thus, mitigation of the panel's contribution to NVH is desirable. Consequently, there is a need for a solar panel design that withstands noise, vibration, and harshness (NVH in the desired application whether architectural, marine, aeronautical, space, and/or other industrial applications resulting in acceptable industrial utility.

Moreover, a solar panel communicates electrically with other components in a vehicle, and the associated circuitry, typically through a junction box, with the wires and solder joints representing potential additional modes of failure as it relates to the panel and surrounding vehicle components. The wires and solder joints of a solar panel often experience maximum stress during its assembly to a vehicle. a solar panel design including a structure for effective strain relief that can accommodate assembly stresses is desirable. Furthermore, a thin solar panel design may be advantageously for reducing the weight and profile of a solar-enabled vehicle and/or industrial application; providing a junction box that minimizes any increase in the vehicle profile, or intrusion into the vehicle interior, is also desirable. Consequently, there is a need for an improved a junction box for a solar panel design a solar-enabled vehicle and/or other in architectural, marine, aeronautical, space, and/or other industrial applications.

What is needed is a solar-enabled body panel and/or method of fabrication that overcomes these and other issues, when coupled to the vehicle structure and/or other industrial application.

### SUMMARY OF THE INVENTION

The present invention advantageously fills the aforementioned deficiencies by providing an apparatus, system and method of mechanically and electrically coupling one or more curved, laminated, solar-enabled vehicular body panels to a vehicle structure.

It is an object of the present invention to provide an interface that mechanically and/or electrically couples a solar panel to a vehicle frame, the interface adapted to provide the panel with the ability to withstand loading conditions.

It is also an object of the present invention to provide an interface adapted to reduce or eliminate NVH, wherein for example, the interface acts as a vibration barrier.

It is also an object of the present invention to provide an interface adapted to provide effective strain relief to one or more components of the electrical system. In one aspect, an improved junction box may provide reliable electrical terminations under harsh installation and operational conditions including strain relief of the wires and solder joints.

It is also an object of the present invention to provide an interface of optimized, or otherwise reduced material, to maintain vehicle profile and reduce intrusion into the vehicle interior.

Contributing to the benefits exhibited by one or more of the aforementioned objects according to the present invention, the interface may comprise one or more layers including a damper having isotropic and/or anisotropic characteristics.

According to an object of the present invention, a damper may comprise a viscoelastic material. The viscoelastic material may be selected based upon a desirable loss tangent, as a function of operating temperatures, or other properties of the vehicle and/or environment.

It is an object of the present invention to provide a solar-enabled body panel that may be mass produced at low cost.

Other desirable features and characteristics including will become apparent from the subsequent detailed description, the drawings, and the appended claims, when considered in view of this summary.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified.

For a better understanding of the present disclosure, reference will be made to the following Detailed Description, which is to be read in association with the accompanying drawings, which are incorporated in and constitute a part of this specification, show certain aspects of the subject matter disclosed herein and, together with the description, help explain some of the principles associated with the disclosed implementations, wherein:

FIG. 1A illustrates a perspective exploded view of a solar-enabled body panel sub-assembly and vehicle frame, according to an embodiment of the invention;

FIG. 1B illustrates a section view taken along section A-A of FIG. 1A, of a solar-enabled body panel sub-assembly and vehicle frame, according to an embodiment of the invention;

FIG. 2 illustrates a section view of a solar panel and flexible junction box assembly according to detail B of FIG. 1B wherein electrical connection is made through a wire-to-wire solder joint, according to an embodiment of the invention;

FIG. 3 illustrates a section view of a solar panel and flexible junction box assembly according to detail B of FIG. 1B wherein electrical connection is made through a solder board and solder joints, according to an embodiment of the invention; and

FIG. 4 illustrates a section view of a solar panel and rigid junction box assembly according to detail B of FIG. 1B wherein electrical connection is made through a solder board and solder joints, according to an embodiment of the invention.

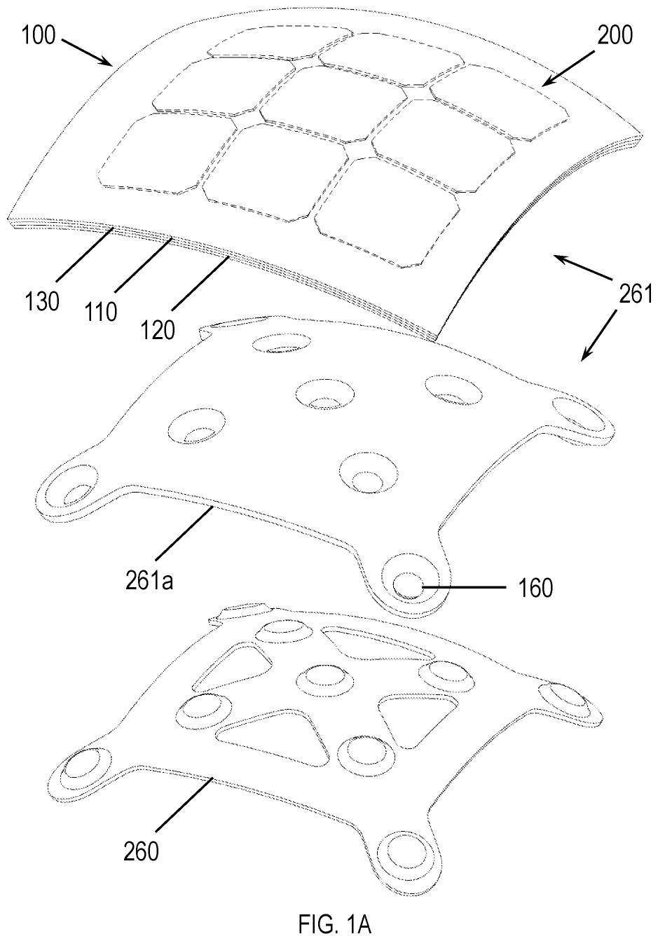

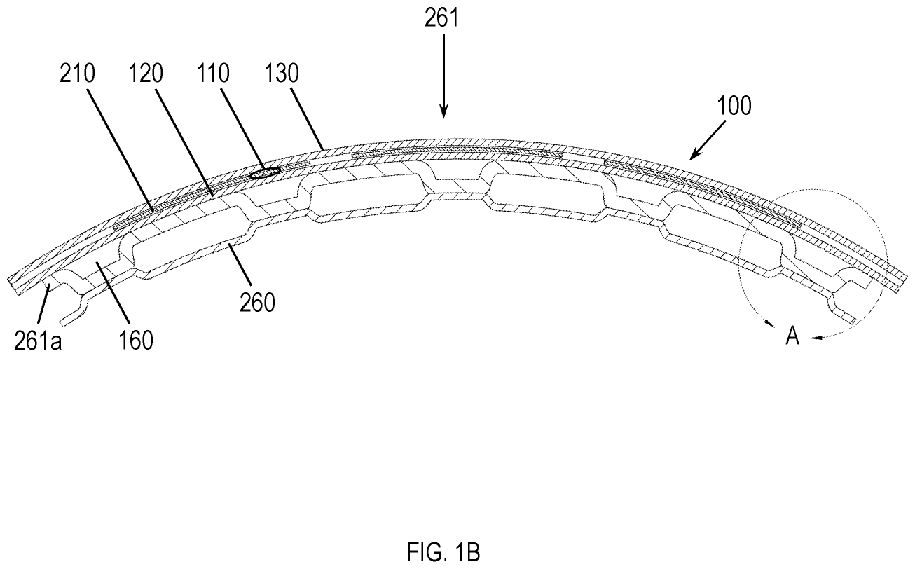

The drawings, including FIGS. 1A-1B and 2-4, may contain sizes and shapes of respective portions that are appropriately exaggerated for ease of understanding. Therefore, the comparative sizes and/or shapes displayed in the drawings should be considered non-limiting.

### DETAILED DESCRIPTION

Non-limiting embodiments of the present invention will be described below with reference to the accompanying drawings, wherein like reference numerals represent like elements throughout. While the invention has been described in detail with respect to the preferred embodiments thereof, it will be appreciated that upon reading and understanding of the foregoing, certain variations to the preferred embodiments will become apparent, which variations are nonetheless within the spirit and scope of the invention. The drawings featured in the figures are provided for the purposes of illustrating some embodiments of the invention and are not to be considered as a limitation thereto.

The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

Reference throughout this document to “some embodiments”, “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of elements, functions, steps or acts are in some way inherently mutually exclusive.

Term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

FIG. 1A illustrates the solar-enabled roof body panel 261 sub-assembly and vehicle frame 260 to which it attaches, according to the present invention. For example, body panel 261 and vehicle frame 260 coupled thereto may be a vehicle hood, door panel, body panel, trunk, etc. Furthermore, body panel 261 and vehicle frame 260 may be considered as any solar panel application having a complex shape, and may have utility in architectural, marine, aeronautical, space, and/or other industrial applications. While this disclosure may refer to and depict an exemplary vehicle roof panel embodiment to describe certain features of the invention, it is not specifically limited thereto as a solar panel design has industrial application in diverse fields such as, for example, vehicular, marine, space, and architectural applications.

Referring to FIGS. 1A-1B to 4, the body panel 261 may comprise a solar panel 100 with two axes of curvature. The present invention also can use methods of manufacturing a solar panel 100, such as a laminated panel 101, as described in certain applications commonly owned by Applicant, which are incorporated herein by reference in their entirety: U.S. patent application Ser. No. 18/169,576, entitled Curved Laminated Solar Panel And Method Of Manufacture Thereof, filed on Feb. 15, 2023; and PCT/US2023/064679, entitled “Laminator Apparatus And Method Of Making Curved Laminated Solar Panel”, filed on Mar. 18, 2023. The solar panel 100 may be a laminate comprising a core 110 encapsulating a solar cell array 200 and sandwiched by a substrate 120 and superstrate 130. The body panel 261 may further comprise an interface 261a between the solar panel 100 and the vehicle frame 260. The vehicle frame 260 may be referred to herein as a “spider”. The interface 261a may be configured as a support structure, may be configured to act as a damper for NVH or other force-mitigating purposes, and/or may be configured as one or more low-profile junction boxes 160 for the solar panel 100 terminals. During manufacturing, the interface 261a (also referred to as a “damper” in certain embodiments) may be coupled to the solar panel 100 via an adhesive or other coupling method, and the solar panel 100 terminations may be assembled therein to form a roof panel sub-assembly 261 suitable for installation onto the frame of a vehicle. The spider 260 may be installed on or integrated with the vehicle frame prior to the installation of the roof panel sub-assembly 261. The junction box(es) 160 may serve as the mating elements between the roof panel sub-assembly 261 and the spider 260.

The assembled roof panel 261 and spider 260 are shown in FIG. 1B where the solar panel 100 is supported along its entirety by the semi-flexible damper 261a. The roof panel sub-assembly 261 may be mated to the vehicle frame 260 at the junction box(es) 160, leaving a gap between the frame 260 and panel 261. In this way, the solar-enabled body panel 261 may be free to flex a small amount to accommodate static and dynamic loads, including the weight of objects placed on the solar panel 100, expansion and contraction due to temperature, deflection due to wind, and road induced vibrations. However, body panel 261 may be constrained to flex such that stress on the solar cells 210 remains below the damage threshold of the cells. In one or more embodiments, the damper 261a may completely fill the space between the solar panel 100 and spider 260, except for voids forming the junction boxes. Alternatively, in one or more embodiments, damper 261a may be disposed along only a portion of the solar panel 100 and/or a portion of the vehicle frame 260.

Generally speaking, both the geometry and material properties of the damper 261a have a bearing on damper performance. As an example of the former, a thicker damper 261a may have the advantage of greater noise reduction due to vibration. Regarding the latter, the damper 261a may take advantage of the properties of a viscoelastic material to dissipate energy under dynamic loads and reduce the risk of damage to the solar cells at the panel resonance frequency. Examples of viscoelastic materials include rubber, polyurethane, and PVC. The damper material can be selected based on its loss tangent. The loss tangent in this context refers to the ratio of loss modulus to storage modulus—in other words, energy lost to heat during compression vs. elastic energy stored during loading. This can be characterized by a material's hysteresis loop; the greater the hysteresis, generally the larger the loss tangent, which indicates greater damping capabilities. The loss tangent is generally temperature dependent. It is therefore advantageous to select a material with a specified minimum loss tangent within the operational temperature range of the vehicle. An example of such a material is Sorbothane® sold by Sorbothane, Inc., Kent, Ohio, which has a durometer of 30 and a loss tangent of 0.72-0.80 over a temperature range of −20° to +140°. Damper 261a may further comprise anisotropic characteristics, or isotropic characteristics, depending on directional attributes of the expected loads. Damper 261a may further be homogeneous throughout. Alternatively, damper 261a may be heterogeneous, such as, for example, comprising a plurality of compositional layers. In one embodiment, at least one layer of damper 261a may comprise a viscoelastic material, and at least one other layer may comprise a rigid material, such as a metal. Damper 261a may be substantially of uniform thickness, or alternatively may be of varying thickness.

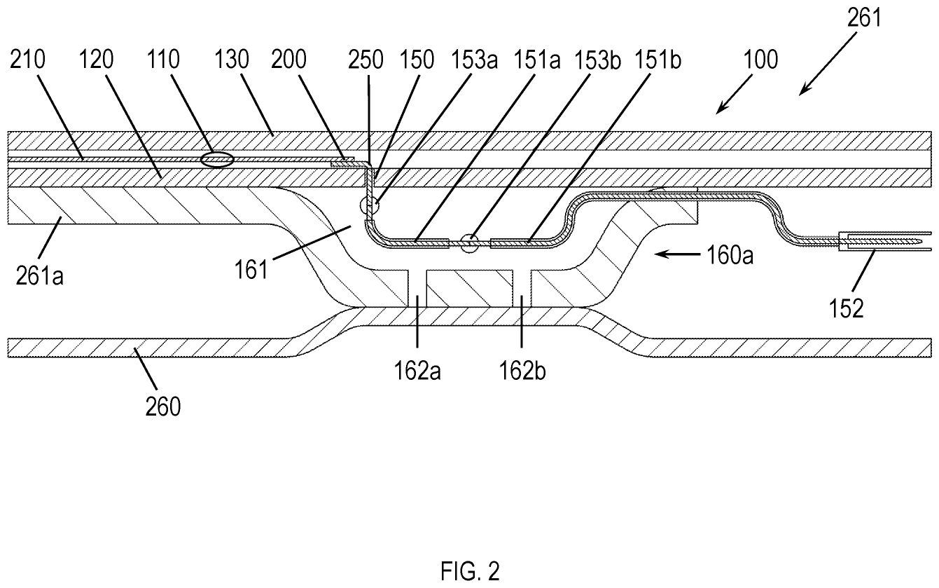

The solar panel 100 may be electrically connected to the vehicle via terminations on the interior-facing side of the panel 100. Such terminations may take several forms as exhibited in FIGS. 2-4. In a first embodiment, FIG. 2 shows the solar body panel 261 assembled to the spider 260 wherein the damper 261a serves as a structural support and flexible junction box 160a for the solar panel 100, and an interface layer between the solar panel 100 and spider 260. The damper layer 261a comprises a semi-flexible material and may be adhered to the solar panel 100. At the termination end of the solar cell array 200, a junction box 160a may be formed in the damper 261a in the shape of a pocket creating a space for an electrical junction. The busbar 250 of the solar cell array 200 passes from the core 110 of the solar panel through the substrate 120 via a feedthrough 150 where it may be coupled to a wire 151a via a solder joint 153a. The other end of the wire 151a may be coupled directly to a connector cable 151b via a solder joint 153b. The cable wire 151b passes underneath or through the wall of the junction box 160a and may be terminated in a connector 152. The semi-flexible junction box 160a may be potted with a viscoelastic sealant 161, such as silicone. The sealant 161 may be injected into a first of two openings 162a disposed in the bottom of the junction box 160a whereupon it displaces the air inside and exits through a second opening 162b. Strain relief may be achieved by looping, coiling or otherwise shaping (e.g., serpentine) the wires 151a-151b and/or by flexing of the potting material 161. The damper 261a/solar panel 100 sub-assembly 261 may then be mated to the spider 260 which may be pre-assembled to the vehicle.

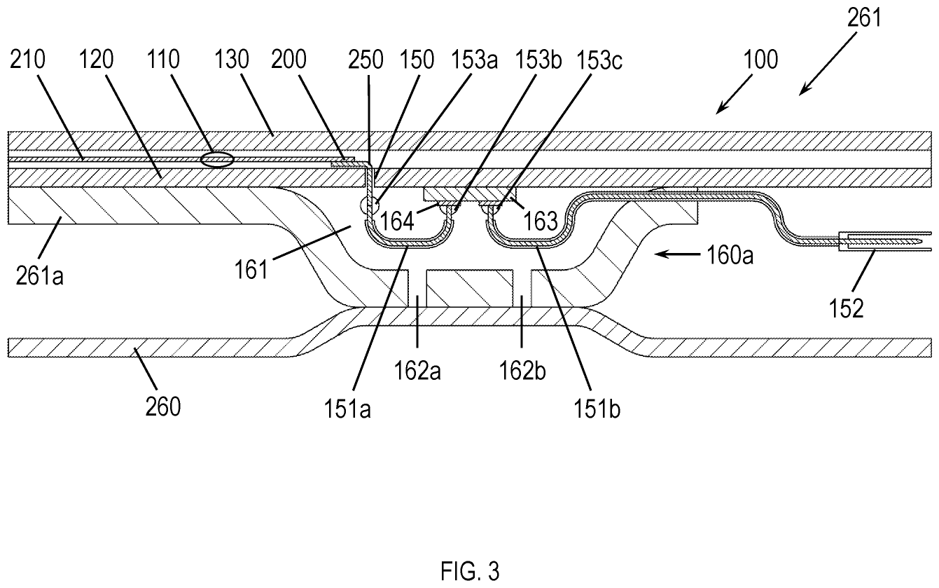

In a second embodiment, FIG. 3 illustrates the solar body panel 261 assembled to the spider 260 wherein the damper 261a serves as a structural support and flexible junction box 160a for the solar panel, and an interface layer between the solar panel 100 and spider 260. The damper layer 261a comprises a semi-flexible material and may be adhered to the solar panel 100. At the termination end of the solar cell array 200, a junction box 160a may be formed in the damper 261a in the shape of a pocket creating a space for an electrical junction. The busbar 250 of the solar cell array 200 passes from the core 110 of the solar panel through the substrate 120 via a feedthrough 150 where it may be coupled to a wire 151a via a solder joint 153a. The other end of the wire 151a may be coupled to a solder board 163 which may be adhered to the solar panel 100. The solder board 163 comprises a pair of electrically coupled bond pads 164 which may be connected to the busbar wire 151a and termination cable 151b via solder joints 153b-153c, thereby providing strain relief against tension on the cable 151b. The cable wire 151b passes underneath or through the wall of the junction box 160a and may be terminated in a connector 152. The junction box 160a may be potted with a viscoelastic sealant 161, such as silicone. The sealant 161 may be injected into a first of two openings 162a disposed in the bottom of the junction box 160a whereupon it displaces the air inside and exits through a second opening 162b. The damper 261a/solar panel 100 sub-assembly 261 may then be mated to the spider 260 which may be pre-assembled to the vehicle.

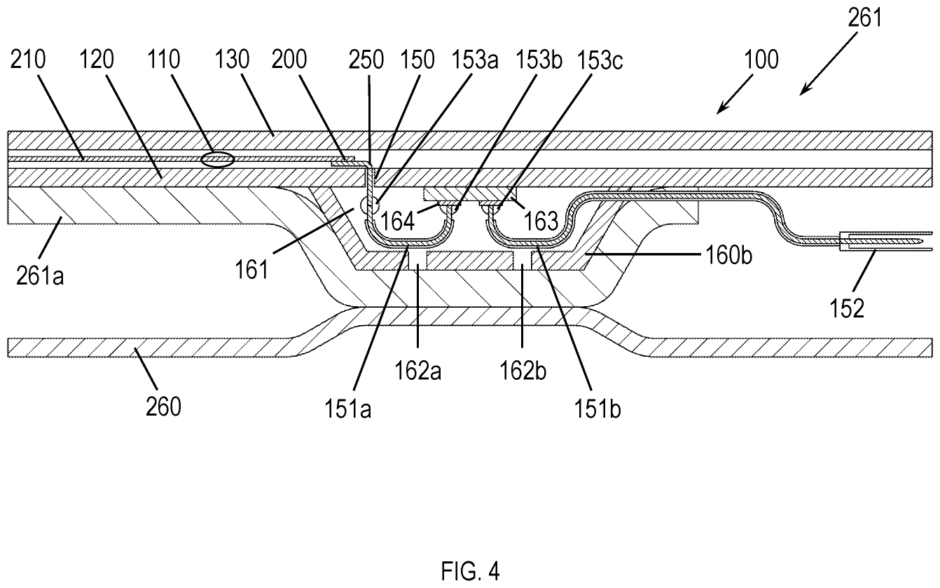

In a third embodiment, FIG. 4 shows the solar body panel 261 assembled to the spider 260 wherein the damper 261a serves as a structural support for the solar panel, and an interface layer between the solar panel 100 and spider 260. The damper layer 261a comprises a semi-flexible material and may be adhered to the solar panel 100. At the termination end of the solar cell array 200, a rigid insert 160b may be coupled, e.g., adhered, to the solar panel 100 and/or damper 261a creating a space for an electrical junction. The busbar 250 of the solar cell array 200 passes from the core 110 of the solar panel through the substrate 120 via a feedthrough 150 where it may be coupled to a wire 151a via a solder joint 153a. The other end of the wire 151a may be coupled to a solder board 163 which may be adhered to the solar panel 100. The solder board 163 comprises a pair of electrically coupled bond pads 164 which may be connected to the busbar wire 151a and termination cable 151b via solder joints 153b-153c, thereby providing strain relief against tension on the cable 151b. The cable wire 151b passes underneath or through the wall of the rigid insert 160b and may be terminated in a connector 152. The rigid insert 160b may be potted with a viscoelastic sealant 161, such as silicone. The sealant 161 may be injected into a first of two openings 162a disposed in the bottom of the junction box whereupon it displaces the air inside and exits through a second opening 162b. The damper 261a and solar panel 100 sub-assembly 261 may then be mated to the spider 260 which may be pre-assembled to the vehicle.

Applications of the aforementioned embodiments are not necessarily limited to vehicle or roof panel applications. For example, one or more of the embodiments may be directed to a hood, trunk or other panel that is expected to have panel flexion when secured to the vehicle. Other exemplary applications include, but are not limited to, architectural panels exposed to light for interior use, vehicle panels, marine panels, aeronautical, spacecraft, and other panel applications.

While certain configurations of structures have been illustrated for the purposes of presenting the basic structures of the present invention, one of ordinary skill in the art will appreciate that other variations are possible which would still fall within the scope of the appended claims. Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A solar module comprising:
a solar panel including at least one solar cell;
a frame; and
a damper disposed therebetween, said damper forming at least a portion of one or more junction boxes, said junction box(es) housing terminations of said solar panel, said damper adapted to dampen, or otherwise absorb energy from an impact force directed thereto.

2. The solar module of claim 1, wherein said damper comprises a viscoelastic material.

3. The solar module of claim 2, wherein said one or more junction boxes are mechanically and/or electrically coupled to said terminations by one or more wire-to-wire solder joints.

4. The solar module of claim 1, wherein said damper constrains flexing of said solar cells below the damage threshold of said solar cells.

5. The solar module of claim 1 further comprising a rigid insert forming at least another portion of said one or more junction boxes.

6. The solar module of claim 5, wherein said one or more junction boxes are mechanically and/or electrically coupled to said terminations by one or more wire-to-wire solder joints.

7. The solar module of claim 1 further comprising a potting compound disposed within said one or more junction boxes.

8. A vehicle comprising:
a solar panel including at least one solar cell;
a frame; and
a damper disposed therebetween, said damper forming at least a portion of one or more junction boxes, said junction box(es) housing terminations of said solar panel, said damper adapted to dampen, or otherwise absorb energy from, a force.

9. The vehicle of claim 1, wherein said damper comprises a viscoelastic material.

10. The vehicle of claim 9, wherein said one or more junction boxes are mechanically and/or electrically coupled to said terminations by one or more wire-to-wire solder joints.

11. The vehicle of claim 1, wherein said damper constrains flexing of said solar cells below the damage threshold of said solar cells.

12. The vehicle of claim 1 further comprising a rigid insert forming at least another portion of said one or more junction boxes.

13. The vehicle of claim 12, wherein said one or more junction boxes are mechanically and/or electrically coupled to said terminations by one or more wire-to-wire solder joints.

14. The vehicle of claim 1 further comprising a potting compound disposed within said one or more junction boxes.
